(19) United States
(12) Patent Application Publication
(10) Pub. No.: US 2015/0061749 A1
(43) Pub. Date: Mar. 5, 2015

(54) GATE DRIVER

(71) Applicant: LSIS CO., LTD., Anyang-si (KR)

(72) Inventors: GYOUNG HUN NAM, Goyang-si (KR); SUNG HEE KANG, Suwon-si (KR); JONG BAE KIM, Seoul (KR)

(73) Assignee: LSIS CO., LTD., Anyang-si (KR)

(21) Appl. No.: 14/249,068

(22) Filed: Apr. 9, 2014

(30) Foreign Application Priority Data
Sep. 2, 2013 (KR) 10-2013-0104937

(51) Int. Cl. H03K 17/284

(52) U.S. Cl. CPC H03K 17/284
USPC 327/398

(57) ABSTRACT

A gate driver is provided. The gate driver amplifies an input control signal to drive gates of high and low side transistors. A high side driving chip amplifies a high side control signal for controlling the high side transistor and outputs the amplified high side control signal to the gate of the high side transistor. A low side driving chip amplifies a low side control signal and outputs the amplified low side control signal to the gate of the low side transistor. An emitter terminal of the gate of the high side transistor is connected to a collector terminal of the low side transistor. The high side driving chip is separately prepared from the low side driving chip.

### CROSS-REFERENCE TO RELATED APPLICATIONS

Pursuant to 35 U.S.C. §119(a), this application claims the benefit of earlier filing date and right of priority to Korean Application No. 10-2013-0104937, filed on Sep. 2, 2013, the contents of which is incorporated by reference herein in its entirety.

### BACKGROUND

The present disclosure relates to a gate driver, and particularly, to a gate driver for a gate of a high capacity power device such as an insulated gate bipolar transistor (IGBT).

A high voltage 3-phase motor driving device used in an industrial field uses a voltage type inverter using 6 power switching devices such as field effect transistors (FETs) and IGBTs. This kind of inverter is mainly controlled by a pulse width modulation (PWM) driving method. Typically, the PWM driving method is to control an average current by maintaining a voltage constant and applying a current in a pulse type. Here, a PWM control is to control a ratio of a pulse width.

In addition, a gate driver is used for driving the IGBT. An IC of the gate driver means a semiconductor chip essentially used for various industries, such as an industrial inverter, or a vehicle motor. Typically, the gate driver includes all high and low sides in one chip, which has many limitations.

### SUMMARY

Embodiments provide a gate driver driving a high power 3-phase gate of, for example, an insulate gate bipolar mode transistor (IGBT) and capable of minimizing interferences among phases due to a high voltage.

In one embodiment, a gate driver amplifying an input control signal to drive gates of high and low side transistors, includes: a high side driving chip amplifying a high side control signal for controlling the high side transistor and outputting the amplified high side control signal to the gate of the high side transistor; and a low side driving chip amplifying a low side control signal and outputting the amplified low side control signal to the gate of the low side transistor, wherein an emitter terminal of the gate of the high side transistor is connected to a collector terminal of the low side transistor, the high side driving chip is separately prepared from the low side driving chip, and the low side driving chip comprises a dead time control unit dead-time controlling the low side control signal and generating the dead-time controlled low side control signal, and an output driver amplifying the dead-time controlled low side control signal and outputting the amplified signal.

The dead time controller may dead-time control the low side control signal on the basis of the high side control signal.

In another embodiment, a method of operating a gate driver, which includes a high side driving chip amplifying an input control signal and driving a gate of a high side transistor and a low side driving chip driving a gate of a low side transistor, the method includes: amplifying a high side control signal for controlling the high side transistor and outputting the amplified high side control signal to the gate of the high side transistor; amplifying a low side control signal and outputting the amplified low side control signal to the gate of the low side transistor; dead-time controlling the low side control signal and generating the dead-time controlled low side control signal; and amplifying the dead-time controlled low side control signal and outputting the amplified dead-time controlled low side control signal, wherein an emitter terminal of the gate of the high side transistor is connected to a collector terminal of the low side transistor, and the high side driving chip is separately prepared from the low side driving chip.

The dead-time controlling of the low side control signal may include dead-time controlling the low side control signal on the basis of the high side control signal.

The details of one or more embodiments are set forth in the accompanying drawings and the description below. Other features will be apparent from the description and drawings, and from the claims.

### BRIEF DESCRIPTION OF THE DRAWINGS

FIG. 1 illustrates a gate driver according to an embodiment.

FIG. 2 is a block diagram illustrating a gate driver according to an embodiment.

FIG. 3 is a flow chart illustrating an operation of a gate driver according to an embodiment.

FIG. 4 illustrates a gate driver according to another embodiment.

FIG. 5 is a block diagram illustrating a gate driver according to another embodiment.

FIG. 6 is a flow chart illustrating an operation of a gate driver according to another embodiment.

### DETAILED DESCRIPTION OF THE EMBODIMENTS

Reference will now be made in detail to the embodiments of the present disclosure, examples of which are illustrated in the accompanying drawings. The present invention can be practiced in various ways and is not limited to the embodiments described herein. In the drawings, parts which are not related to the description are omitted to clearly set forth the present invention and similar elements are denoted by similar reference symbols throughout the specification.

It will be further understood that the terms “comprises” and/or “comprising,” when used in this specification, specify the presence of stated elements but do not preclude the presence or addition of one or more elements thereof.

A gate driver according to an embodiment will be described in detail with reference to the accompanying drawings. The invention may, however, be embodied in many different forms and should not be construed as being limited to the embodiments set forth herein; rather, that alternate embodiments included in other retrogressive inventions or falling within the spirit and scope of the present disclosure can easily be derived through adding, altering, and changing, and will fully convey the concept of the invention to those skilled in the art.

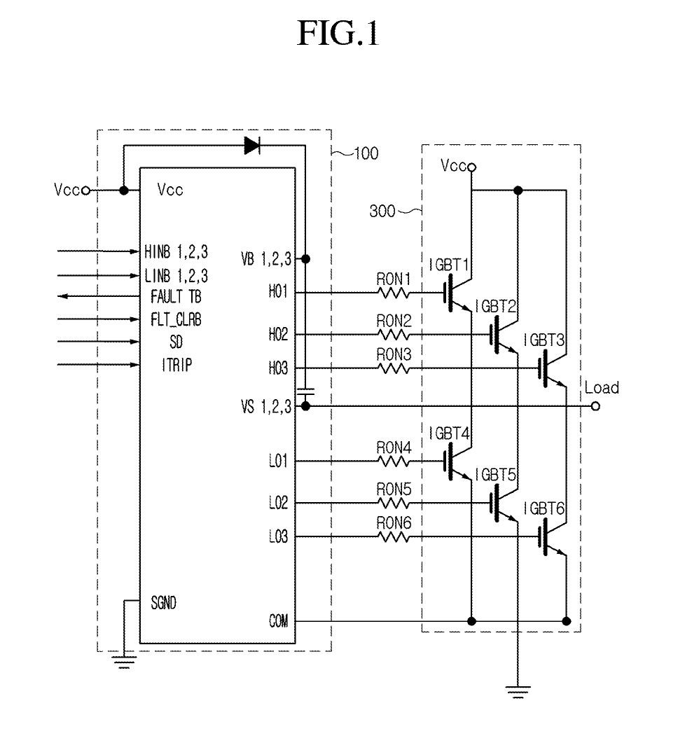

Hereinafter, a gate driver will be described in relation to FIGS. 1 to 3.

FIG. 1 illustrates a gate driver according to an embodiment.

An input end of a gate driver 100 according to an embodiment includes Vcc, HINB 1, 2, 3, LINB 1, 2, 3, FAULT TB, FLT_CLRB, SD, ITRIP, and SGND terminals. The Vcc terminal is a dc voltage input terminal. The HINB 1, 2, 3 terminal is a logic input terminal for a high side gate driver output. The LINB 1, 2, 3 terminal is a logic input terminal for a low side gate driver output. The FAULT TB terminal indicates shutdown due to an overcurrent or undervoltage state. The FLT_CLRB terminal is an input terminal for re-operation after the shutdown due to the overcurrent or undervoltage state. The SD terminal is a signal ground terminal for the soft shutdown. The SGND terminal is a signal ground terminal which is a reference terminal of all signal voltages.

An output end of the gate driver 100 according to an embodiment includes VB 1, 2, 3, HO1, HO2, HO3, VS 1, 2, 3, LO1, LO2, LO3, and COM terminals. The VB 1, 2, 3 terminal is a floating supplying voltage terminal that is not grounded. The HO1, HO2, and HO3 terminals are first, second, and third high side output terminals of the gate driver 100. The LO1, LO2, and LO3 terminals are first, second, and third output terminals of the gate driver 100. The VS 1, 2, 3 terminal is a high voltage floating supply return terminal. The COM terminal is a return terminal of brake and a low side gate driver.

The 3 phase gate driver may have total 6 insulate gate bipolar transistors (IGBTs) connected thereto. The IGBTs are respectively connected to first to third high side output terminals HO1, HO2, and HO3, and first to third low side output terminals LO1, LO2, and LO3. In detail, the first to third high side output terminals HO1, HO2, and HO3 and the first to third low side output terminals LO1, LO2, and LO3 of the gate driver are respectively connected to one ends of resistors RON1, RON2, RON3, RON4, RON5, and RON6. The other ends of the resistors RON1, RON2, RON3, RON4, RON5, and RON6 are respectively connected to gate terminals of IGBTs IGBT1, IGBT2, IGBT3, IGBT4, IGBT5, and IGBT6.

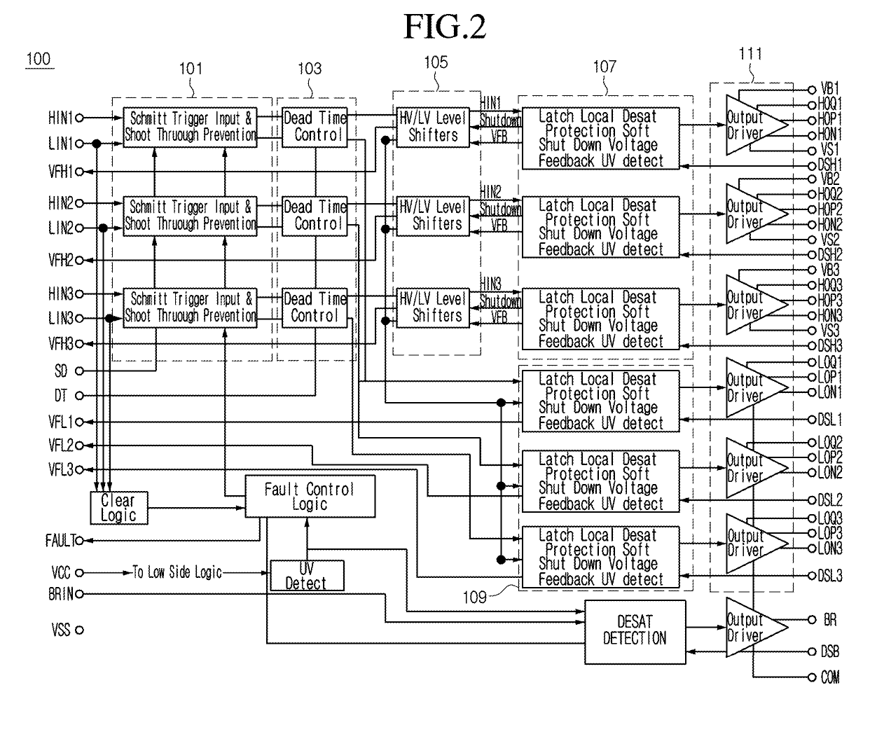

FIG. 2 is a block diagram illustrating a gate driver according to an embodiment.

The gate driver 100 includes an input control unit 101, a dead time control unit 103, a level shifter 105, a first latch and protection circuit 107, a second latch and protection circuit 109, and an output driver 111.

The input control unit 101 controls a control signal input in a pulse type so that the control signal has a constant amplitude and delivers the control signal. The input control unit 101 may be a Schmitt rigger circuit. The Schmitt trigger circuit is a circuit outputting a constant output by abruptly operating when an amplitude of the pulse input is greater than a predetermined value, and instantly stopping operation when the amplitude is the predetermined value or smaller.

The dead time control unit 103 dead-time-controls received low and high side control signals so that the received low and high side control signals are not simultaneously delivered and delivers the dead-time controlled low and high side control signals. The dead time control is to prevent a very large current from flowing through an element and destroying the element due to simultaneous application of the high and low side control signals. In detail, the dead time control is to control the high and low side control signals so that the high and low side control signals are amplified in a sufficient time interval and delivered to gates.

The level shifter 105 level-shifts the dead-time-controlled high side control signal to a high level voltage of 600 v or higher. Since a basic voltage source is controlled through a dc voltage Vcc, the low side control signal does not need a level shift by the level shifter 105.

The first latch and protection circuit 107 includes a latch and a protection circuit. When receiving a level-shifted signal, the latch stores the level-shifted signal, and, when not receiving a signal, the latch delivers the stored level-shifted signal. The protection circuit performs a soft shutdown on the gate driver 100 for protecting gates when voltages of the gates are very low or the gates are in desaturation states. Whether the gate voltages are low may be determined by determining whether the gate voltages are lower than a predetermined reference voltage. When a gate voltage is low, an IGBT may operate in an active region and be rapidly over-heated. Accordingly, it is necessary to perform soft shutdown on the gate driver 100 to protect the gates. In addition, in case of desaturation state, an emitter terminal voltage is in about 5 to about 8 v, a gate terminal voltage is high, and a current passing through the IGBT is very larger than that in a normal operation of the IGBT. Accordingly, it is necessary to protect the gates by performing soft shutdown on the gate driver 100.

The second latch and protection circuit 109 operates identically to the first latch and protection circuit 107. However, the second protection circuit 109 receives the low side control signal which is not level-shifted. Accordingly, the second latch and protection circuit 109 receives and delivers the low side control signal. When the gate voltages are very low or in desaturation states, the second latch and protection circuit 109 performs soft shut down on the gate driver 100 for protecting the gates.

The output driver 111 amplifies a received signal and outputs the amplified signal.

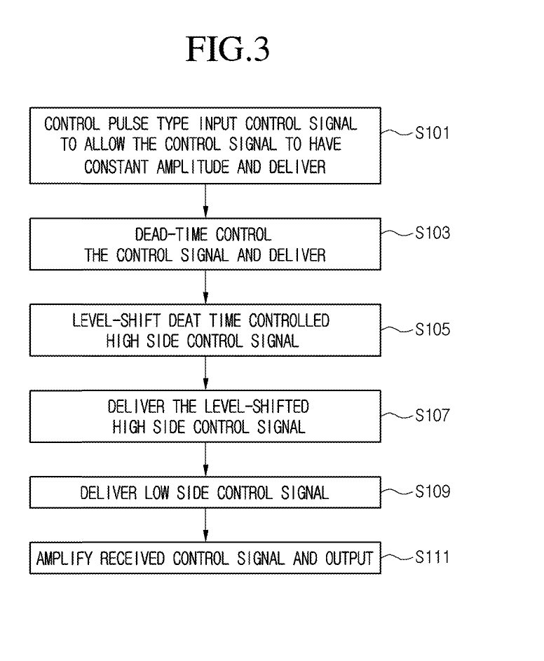

FIG. 3 is a flowchart illustrating an operation of a gate driver according to an embodiment.

The input control unit 101 controls a control signal input in a pulse type so that the control signal has a constant amplitude and delivers the control signal (operation S101). In particular, a Schmitt trigger circuit may control the control signal input in the pulse type.

The dead time control unit 103 dead-time controls not to allow received low and high side control signals to be simultaneously delivered and delivers the dead-time controlled low and high side control signals (operation S103). In detail, the dead time control unit 103 may deliver the low side control signal after a constant time passes from when the high side control signal is delivered.

The level shifter 105 level-shifts the dead-time controlled high side control signal to a high level voltage of 600 v or higher (operation S105).

When receiving the level-shifted signal, the first latch and protection circuit 107 stores the received signal, and, when not receiving the signal, delivers the stored signal (operation S107). Here, when the gate voltage is very low or in a desaturation state, the first latch and protection circuit 107 performs soft shut down on the gate driver 100. Whether the gate voltage is low may be determined by whether the gate voltage is lower than a predetermined voltage.

When receiving the level-shifted signal, the second latch and protection circuit 109 stores the received signal, and, when not receiving the signal, delivers the stored signal (operation S109). Here, when the gate voltage is very low or in a desaturation state, the second latch and protection circuit 109 performs soft shut down on the gate driver 100.

The output driver 111 amplifies the received signal and outputs the amplified signal (operation S111). The gate operates according to the amplified signal.

In such a way, when the high and low sides of the gate driver 100 are included in one chip, simultaneous operations and interferences among phases for a high voltage signal may occur for each phase of U, V, and W phases. Accordingly, malfunction may occur and a gate driver 100 for addressing the above-described limitations is necessary.

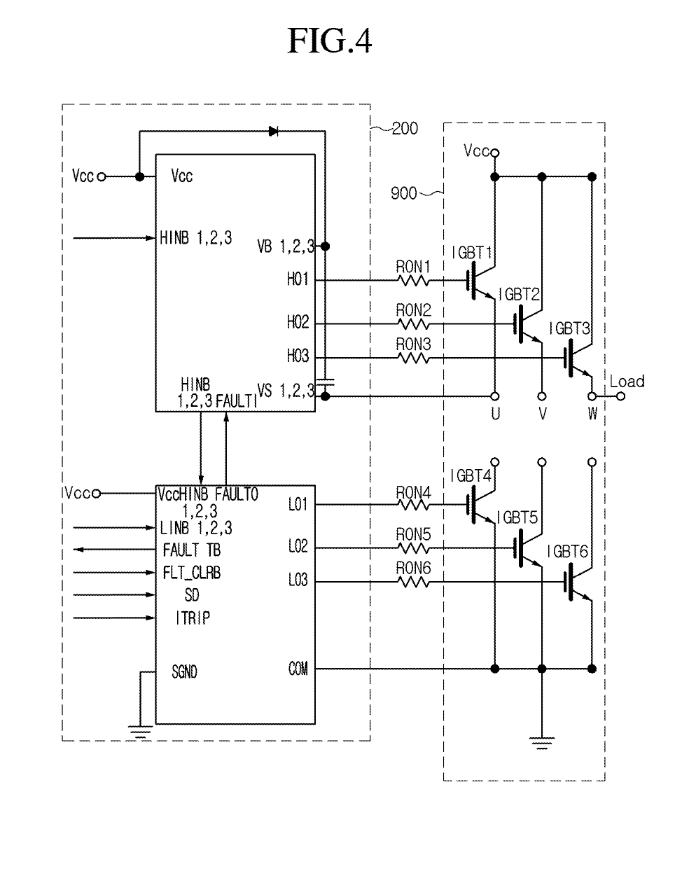

FIG. 4 illustrates a gate driver according to another embodiment.

A gate driver 200 according to the other embodiment includes a high side driving chip 500 and a low side driving chip 700, each of which is separately prepared.

An input end of the high side driving chip 500 of the gate driver 200 according to the other embodiment includes Vcc and HINB 1, 2, 3 terminals. The HINB 1, 2, 3 terminal is a logic input terminal for an output of the gate driver. The Vcc terminal is a dc voltage input terminal.

An output end of the high side driving chip 500 of the gate driver 200 according to the other embodiment includes VB 1, 2, 3, HO1, HO2, HO3, and VS 1, 2, 3 terminals. The VB 1, 2, 3 terminal is a floating supply voltage terminal supplying a voltage without being grounded. The HO1, HO2, and HO3 terminals are first, second, and third output terminals of the high side driving chip 500 of the gate driver 200.

Furthermore, the high side driving chip 500 of the gate driver 200 according to the other embodiment includes the HINB 1, 2, 3 output terminal on one side thereof. A high side control signal which is received through the HINB 1, 2, 3 input terminal is output through the HINB 1, 2, 3 output terminal. A shut down signal due to an abnormal operation according to a subvoltage or overcurrent state is received from the low side driving chip 700 through FAULTI terminal, which is an input terminal on a side of the high side driving chip 500.

An input end of the low side driving chip 700 of the gate driver 200 according to the embodiment includes LINB 1, 2, 3, FALUTI TB, FLT_CLRB, SD, ITRIP, and SGND terminals. The LINB 1, 2, 3 terminal is a logic input terminal for a gate driver output of the low side driving chip 700. The FALUTI TB terminal indicates shut down due to an overcurrent or undervoltage state. The FLT_CLRB terminal is an input terminal for re-operation after shut down due to the overcurrent or undervoltage state. The SD terminal is an input terminal for soft shut down. The ITRIP terminal is an input terminal for soft shut down in occurrence of the overcurrent state. The SGND terminal is a signal ground terminal, which is a reference terminal for all signal voltages.

An output end of the low side driving chip 700 of the gate driver 200 according to the other embodiment includes LO1, LO2, LO3, and COM terminals. The LO1, LO2, and LO3 terminals respectively represent first, second, and third low side output terminals of the gate driver 200. The VS 1, 2, 3 terminal is a high voltage floating supply return terminal. The COM terminal is a brake and low side gate driving return terminal.

The low side driving chip 700 of the gate driver 200 according to the other embodiment includes INB 1, 2, 3, input terminal on a side thereof. The side HINB 1, 2, 3 input terminal receives a high side control signal from the high side driving chip 500. In addition, the low side driving chip 700 includes FAULT0 output terminal on a side thereof. A shut down signal is output from the FALUT0 output terminal due to an abnormal operation according to an undervoltage or overcurrent state.

A 3-phase gate driver according to an embodiment may include total 6 IGBTs. Each of the IGBTs is connected to the first to third output terminals HO1, HO2, and HO3 of the high side driving chip 500 of the gate driver and the first to third output terminals LO1, LO2, and LO3 of the low side driving chip 700 of the gate driver. In detail, one ends of first to sixth resistors RON1, RON2, RON3, RON4, RON5, and RON6 are respectively connected to the first to third output terminals HO1, HO2, and HO3 of the high side driving chip 500 and the first to third output terminals LO1, LO2, and LO3 of the low side driving chip 700 of the gate driver. The other ends of the first to sixth resistors RON1, RON2, RON3, RON4, RON5, and RON6 are respectively connected to the gate terminals of first to sixth IGBTs IGBT1, IGBT2, IGBT3, IGBT4, IGBT5, and IGBT6.

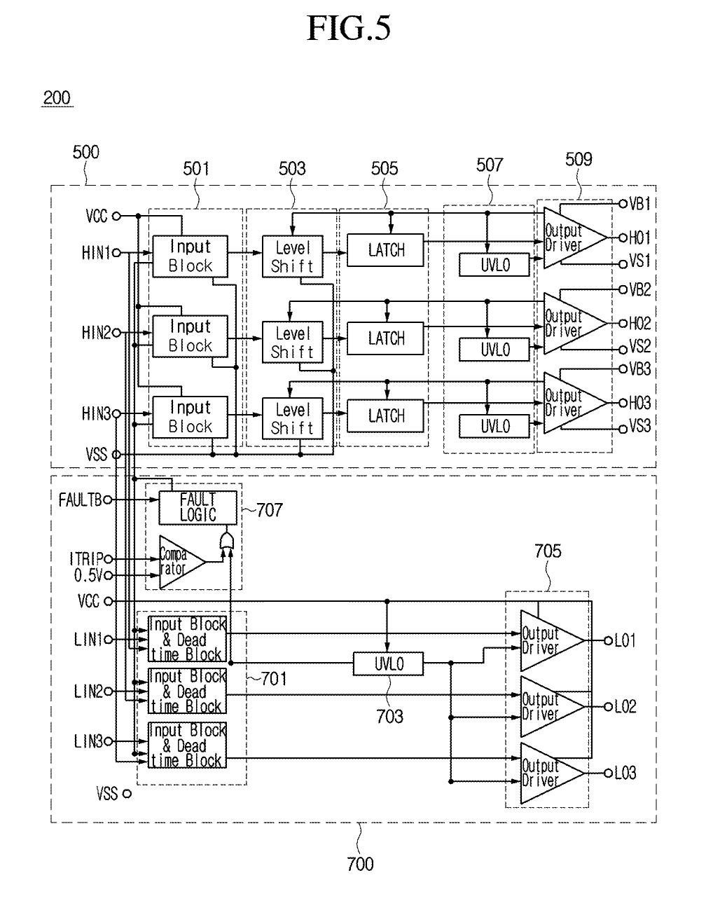

FIG. 5 is a block diagram of a gate driver according to another embodiment.

The gate driver 200 includes a high side driving chip 500 and a low side driving chip 700. The high side driving chip 500 includes an input control unit 501, a level shifter 503, a first latch 505, a low voltage sensing unit 507, and an output driver 509.

The input control unit 501 controls a control signal input in a pulse type so that an amplitude thereof is constant, and delivers the control signal. The input control unit 501 may be a Schmitt trigger circuit. The Schmitt trigger circuit is a circuit for obtaining a constant output by abruptly operating when an amplitude of the pulse input exceeds a predetermined value and instantly stopping operation when the amplitude of the pulse input is the predetermined value or smaller.

The level shifter 503 level-shifts the controlled high side control signal to a high level voltage of about 600 v or higher.

When receiving the level-shifted control signal, the first latch 505 stores it, and delivers the stored signal when not receiving the level-shifted control signal.

When the gate voltage is very low, the low voltage sensing unit 507 outputs a low voltage sensing signal. Whether the gate voltage is a low voltage may be determined by whether the gate voltage is lower than a predetermined reference signal. The high side driving chip 500 is softly shut down according to the low voltage sensing signal.

The output driver 509 amplifies the received control signal and outputs the amplified signal.

The low side driving chip 700 includes an input controller and dead time control unit 701, a protection circuit 703, an output driver 705, and a fault logic circuit 707.

The input controller and dead time control unit 701 includes an input controller and a dead time control unit. The input controller controls a control signal input in a pulse type so that an amplitude thereof is constant, and delivers the control signal. The control unit may be a Schmitt trigger circuit. The dead time control unit dead-time-controls the received high and low side control signals so that the high and low side control signals are not simultaneously delivered to the gates, and delivers the dead-time controlled high and low side signals. Accordingly, the dead time control unit is necessary to be connected to the input control unit 501 of the high side driving chip 500 in order to be able to determine the high side signal. The gate driver 200 according to the other embodiment receives the high side control signal through the side HINB 1, 2, 3 terminal.

In case of very low voltage of the gate voltage, the low voltage sensing unit 703 outputs the low voltage sensing signal.

The output driver 705 amplifies the received signal and outputs the amplified signal.

When an input having a value of a reference value or greater is input through the DALUTB or ITRIP terminal, or the low voltage sensing unit 703 outputs a soft shut down signal, the fault logic circuit 707 performs soft shut down on all operations of the high and low side driving chips 500 and 700. Accordingly, since not only the low side driving chip 700 but the high side driving chip 500 is also to be softly shut down, the fault logic circuit 707 delivers the soft shut down signal through the FAULTI terminal.

Since the gate driver according to the other embodiment includes the high and low sides as separate chips as described above, interferences due to each phase do not occur even in high power. Furthermore, an effect on the low side driving chip 700 due to heat generated by the high side driving chip 500 during operation of the gate driver can be reduced and an effect on the high side driving chip 500 due to heat generated by the low side driving chip 700 can also be reduced.

In addition, according to an embodiment, the chip size in case where the high and low side driving chips 500 and 700 are included in one chip is larger than that in case where the sizes of the high and low side driving chips 500 and 700 according to another embodiment are summed. Accordingly, the size of the gate driver according to the embodiment can be reduced, compared to that according to the other embodiment.

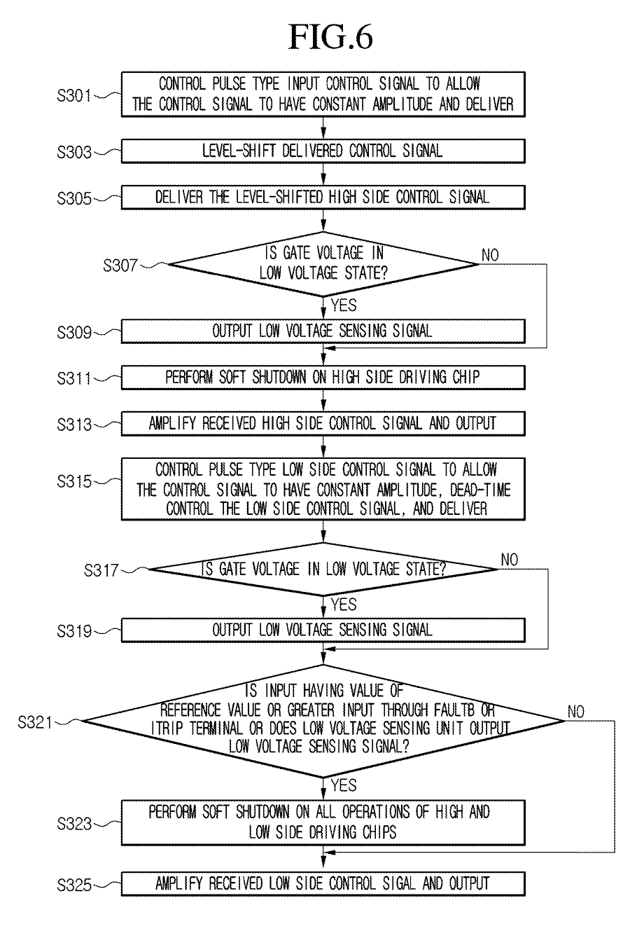

FIG. 6 is a flowchart illustrating a gate driver according to another embodiment.

The input control unit 501 of the high side driving chip 500 controls a control signal input in a pulse type so that an amplitude thereof is constant and delivers the control signal (operation S301).

The level shifter 503 of the high side driving chip 500 level-shifts the received control signal to a high level voltage of 600 v or higher (operation S303).

The latch 505 of the high side driving chip 500 stores the level-shifted control signal when receiving it, and delivers the stored signal when not receiving the level-shifted control signal.

The low voltage sensing unit 507 of the high side driving chip 500 determines when the gate voltage is in a low voltage state where the gate voltage is very low (operation S307). Whether the gate voltage is the low voltage may be determined by whether the gate voltage is lower than a predetermined reference value.

When the gate voltage is in the low voltage state, the low voltage sensing unit 507 of the high side driving chip 500 outputs a low voltage sensing signal (operation S309).

The high side driving chip 500 performs soft shut down according to the low voltage sensing signal (operation S311).

The output driver 309 of the high side driving chip 500 amplifies the received control signal and outputs the amplified signal (operation S313).

The input controller and dead time control unit 701 of the low side driving chip 700 controls a low side control signal so that an amplitude thereof is constant, and dead-time controls and delivers the low side control signal (operation s315).

The dead time control unit dead-time controls the low side control signal on the basis of the high side control signal received through the HINB 1, 2, 3 terminal on the side of the low side driving chip 500 and delivers the dead-time controlled low side control signal. In detail, the dead time control unit may deliver the low side control signal after a constant time passes from when the high side control signal is delivered.

The low voltage sensing unit 703 determines whether the gate voltage is in the low voltage state where the gate voltage is very low (operation S317).

When the gate voltage is in the low voltage state, the low voltage sensing unit 703 performs soft shut down on the low side driving chip 700 of the gate driver 200 and delivers a soft shut down signal to a fault logic circuit 707 (operation S319).

The fault logic circuit 707 determines whether an input having a value of a reference value or greater is input through the FAULTB or ITRIP terminal or the protection circuit 703 outputs the soft shut down signal (operation S321).

When an input having a value of the reference value or greater is input through the FAULTB or ITRIP terminal or the protection circuit 703 outputs the soft shut down signal, the fault logic circuit 707 performs soft shut down on all operations of the high and low side driving chips 500 and 700 (operation S323). Accordingly, since not only the low side driving chip 700 but the high side driving chip 500 is also to be softly shut down, the output of the fault logic circuit 707 is connected to the input controller 501 of the high side driving chip 500, more specifically, through the FAULT0 terminal on the side of the low side driving chip 700 and the FAULTI terminal of the side of the high side driving chip 500.

The output driver 705 of the low side driving chip 700 amplifies the received signal and output the amplified signal (operation S325).

A gate driver according to an embodiment can minimize interferences among phases due to a high voltage which drives a high power 3 phase gates of, for example, an IGBT and minimize an effect of heat generated during operation of the gate driver.

Although embodiments have been described with reference to a number of illustrative embodiments thereof, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. A gate driver amplifying an input control signal to drive gates of high and low side transistors, comprising:
a high side driving chip amplifying a high side control signal for controlling the high side transistor and outputting the amplified high side control signal to the gate of the high side transistor; and
a low side driving chip amplifying a low side control signal and outputting the amplified low side control signal to the gate of the low side transistor,
wherein an emitter terminal of the gate of the high side transistor is connected to a collector terminal of the low side transistor,
the high side driving chip is separately prepared from the low side driving chip, and
the low side driving chip comprises a dead time control unit dead-time controlling the low side control signal and generating the dead-time controlled low side control signal, and an output driver amplifying the dead-time controlled low side control signal and outputting the amplified signal.

2. The gate driver according to claim 1, wherein the dead time controller dead-time controls the low side control signal on the basis of the high side control signal.

3. The gate driver according to claim 2, wherein the dead time control unit delivers the low side control signal after a predetermined time passes from when the high side control signal is delivered.

4. The gate driver according to claim 1, wherein the low side driving chip comprises a fault logic circuit performing soft shut down on all operations of the high and low side driving chips.

5. The gate driver according to claim 4, wherein the low side driving chip comprises a low voltage sensing unit,
when a voltage of the gate is lower than a reference voltage, the low voltage sensing unit inputs a low voltage sensing signal to the fault logic circuit,
when the low side sensing signal is received, the fault logic circuit performs soft shut down on all operations of the high and low side driving chips.

6. A method of operating a gate driver, which comprises a high side driving chip amplifying an input control signal and driving a gate of a high side transistor and a low side driving chip driving a gate of a low side transistor, the method comprising:
amplifying a high side control signal for controlling the high side transistor and outputting the amplified high side control signal to the gate of the high side transistor;
amplifying a low side control signal and outputting the amplified low side control signal to the gate of the low side transistor;
dead-time controlling the low side control signal and generating the dead-time controlled low side control signal; and
amplifying the dead-time controlled low side control signal and outputting the amplified dead-time controlled low side control signal,
wherein an emitter terminal of the gate of the high side transistor is connected to a collector terminal of the low side transistor, and
the high side driving chip is separately prepared from the low side driving chip.

7. The method according to claim 6, wherein the dead-time controlling of the low side control signal comprises dead-time controlling the low side control signal on the basis of the high side control signal.

8. The method according to claim 7, wherein the dead-time controlling of the low side control signal on the basis of the high side control signal comprises delivering the low side control signal after a predetermined time passes from when the high side control signal is delivered.

9. The method according to claim 6, further comprising performing soft shut down on all operations of the high and low side driving chips.

10. The method according to claim 9, wherein the performing of the soft shut down comprises performing the soft shut down on all the operations of the high and low driving chips, when a voltage of the gate are lower than a reference voltage.
